(19) United States
(12) Patent Application Publication
(10) Pub. No.: US 2008/0286495 A1
(43) Pub. Date: Nov. 20, 2008

(54) SYSTEM AND METHOD FOR POWER FUNCTION RAMPING OF SPLIT ANTENNA PECVD DISCHARGE SOURCES

(76) Inventor: Michael W. Stowell, Loveland, CO (US)

Correspondence Address: COOLEY GODWARD KRONISH LLP;ATTN: Patent Group, Suite 1100, 777 - 6th Street, NW, WASHINGTON, DC, 20001, US

(21) Appl. No.: 11/678,448

(22) Filed: Feb. 23, 2007

Related U.S. Application Data
(63) Continuation of application No. 11/264,540, filed on Nov. 1, 2005.

(51) Int. Cl. C23C 16/511; B05C 11/00

(52) U.S. Cl. 427/575; 118/723 VE; 118/699

(57) ABSTRACT

A system and method for depositing films on a substrate is described. One embodiment includes a vacuum chamber; a split conductor housed inside the vacuum chamber; a magnetron configured to generate a power signal that can be applied to at least a portion of the split conductor; a power supply configured to provide a power signal to the magnetron, the power signal including a plurality of pulses; and a pulse control connected to the power supply, the pulse control configured to control the duty cycle of the plurality of pulses, the frequency of the plurality of pulses, and the contour shape of the plurality of pulses.

### PRIORITY

The present application is a continuation of and claims priority to commonly owned and assigned U.S. application Ser. No. 11/264,540, Attorney Docket No. APPL-008/00US, entitled SYSTEM AND METHOD FOR POWER FUNCTION RAMPING OF MICROWAVE LINEAR DISCHARGE SOURCES, which is incorporated herein by reference.

### FIELD OF THE INVENTION

The present invention relates to power supplies, systems, and methods for chemical vapor deposition.

### BACKGROUND OF THE INVENTION

Chemical vapor deposition (CVD) is a process whereby a film is deposited on a substrate by reacting chemicals together in the gaseous or vapor phase to form a film. The gases or vapors utilized for CVD are gases or compounds that contain the element to be deposited and that may be induced to react with a substrate or other gas(es) to deposit a film. The CVD reaction may be thermally activated, plasma induced, plasma enhanced or activated by light in photon induced systems.

CVD is used extensively in the semiconductor industry to build up wafers. CVD can also be used for coating larger substrates such as glass and polycarbonate sheets. Plasma enhanced CVD (PECVD), for example, is one of the more promising technologies for creating large photovoltaic sheets and polycarbonate windows for automobiles.

FIG. 1 illustrates a cut away of a typical PECVD system 100 for large-scale deposition processes—currently up to 2.5 meters wide. This system includes a vacuum chamber 105 of which only two walls are illustrated. The vacuum chamber houses a linear discharge tube 110. The linear discharge tube 110 is formed of an inner conductor 115 that is configured to carry a microwave signal, or other signals, into the vacuum chamber 105. This microwave power radiates outward from the inner conductor 115 and ignites the surrounding support gas that is introduced through the support gas tube 120. This ignited gas is a plasma and is generally adjacent to the linear discharge tube 110. Radicals generated by the plasma and electromagnetic radiation disassociate the feedstock gas(es) 130 introduced through the feedstock gas tube 125 thereby breaking up the feedstock gas to form new molecules. Certain molecules formed during the disassociation process are deposited on the substrate 135. The other molecules formed by the disassociation process are waste and are removed through an exhaust port (not shown)—although these molecules tend to occasionally deposit themselves on the substrate.

To coat large substrate surface areas rapidly, a substrate carrier moves the substrate 135 through the vacuum chamber 105 at a steady rate. Other embodiments however, could include static coating. As the substrate 135 moves through the vacuum chamber 105, the disassociation should continue at a steady rate, and target molecules from the disassociated feed gas are theoretically deposited evenly on the substrate, thereby forming a uniform film on the substrate. But due to a variety of real-world factors, the films formed by this process are not always uniform. And often, efforts to compensate for these real-world factors damage the substrate by introducing too much heat or other stresses. Accordingly, an improved system and method are needed.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

The present invention can provide a system and method for depositing films on a substrate. In one exemplary embodiment, the present invention can include a vacuum chamber; a split conductor housed inside the vacuum chamber; a magnetron configured to generate a power signal that can be applied to at least a portion of the split conductor; a power supply configured to provide a power signal to the magnetron, the power signal including a plurality of pulses; and a pulse control connected to the power supply, the pulse control configured to control the duty cycle of the plurality of pulses, the frequency of the plurality of pulses, and the contour shape of the plurality of pulses.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 illustrates one type of PECVD system;

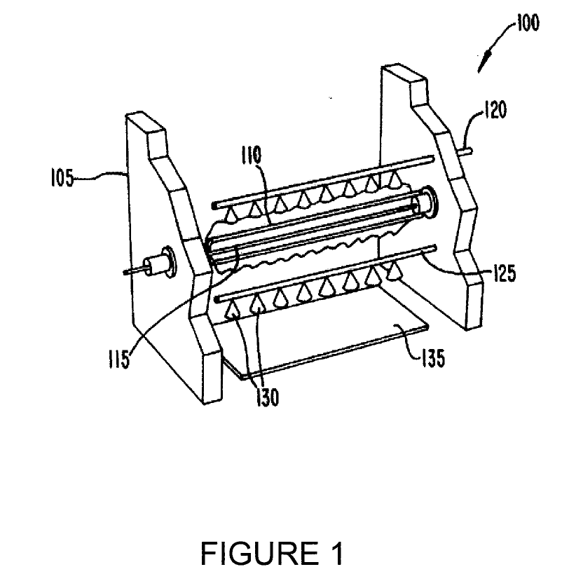

FIG. 2 is an illustration of a linear discharge tube with surrounding, irregular plasma;

FIG. 3 is an illustration of a shielded split antenna arrangement for a linear discharge tube;

FIG. 4 illustrates a power supply for a PECVD system in accordance with one embodiment of the present invention;

FIG. 5 is an alternative depiction of a power supply for a PECVD system in accordance with one embodiment of the present invention;

FIG. 6 is another alternative depiction of a power source for a PECVD system in accordance with one embodiment of the present invention.

FIG. 7 illustrates one example of a pulse-width modulated power signal;

FIG. 8 illustrates one example of a pulse-amplitude modulated power signal;

FIG. 9 illustrates one example of a frequency-modulated power signal; and

FIG. 10 illustrates exemplary power source signals that can be used with the present invention.

### DETAILED DESCRIPTION

In some PECVD processes the typical radical lifetime (time for the loss of and consumption of the radical species) is long enough so that there can be an off time of the plasma during which the radical density remaining is gradually consumed by the deposition of the film and loss mechanisms. Therefore, by controlling the total radical density during these on and off times of the plasma the chemical makeup of the film can be altered, as well as the over all layer properties of the film.

By modulating the power level into the plasma, the on time of the plasma and the timing between the power pulses, the user can make films that were not achievable before in PECVD. The layers could be a single gradient layer or a multiple stack of hundreds to thousands of micro layers with varying properties between each layer. Both processes can create a unique film.

However, as previously described, real-world factors act to limit the quality of films created by deposition systems, including linear microwave deposition systems. One of these limiting factors is an inability to create and maintain uniform plasmas around the linear discharge tube. Non-uniform plasmas result in non-uniform disassociation at certain points along the linear discharge tube, thereby causing non-homogenous deposition on certain portions of the substrate.

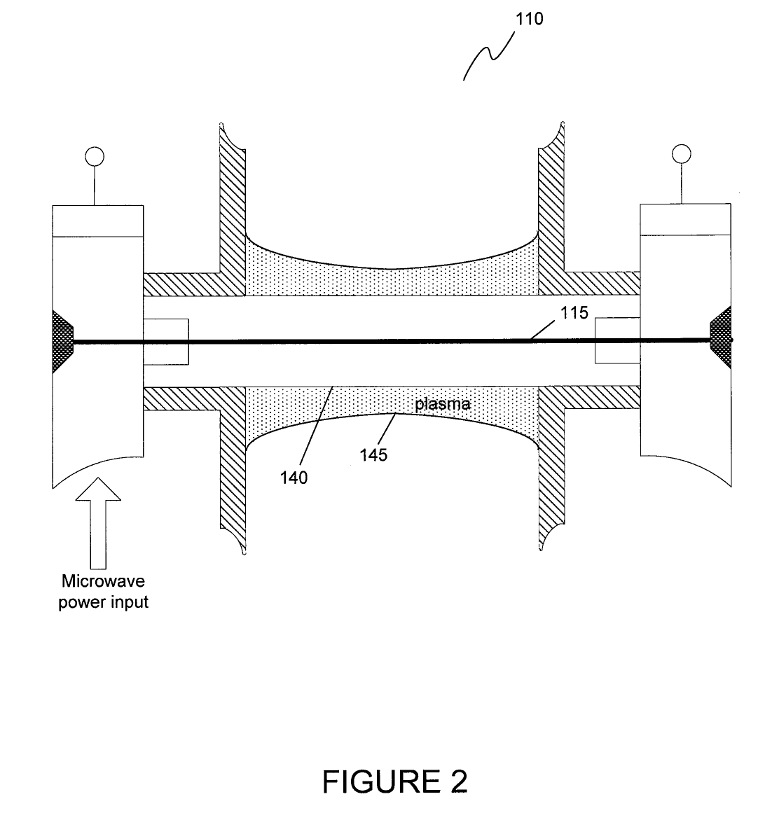

FIG. 2 illustrates a non-uniform plasma formed along typical linear discharge tubes 110 used in microwave deposition systems. For perspective, this linear discharge tube 110 is located inside a vacuum chamber (not shown) and includes an inner conductor 115, such as an antenna, inside a non-conductive tube 140. Microwave power, or other energy waves, is introduced into the inner conductor 115 at both ends of the linear discharge tube 110. The microwave power ignites the gas near the linear discharge tube 110 and forms a plasma 145. But as the microwave power travels toward the center of the linear discharge tube 110, the amount of power available to ignite and maintain the plasma drops. In certain cases, the plasma 145 near the center of the linear discharge tube 110 may not ignite or may have an extremely low density compared to the plasma 145 at the ends of the linear discharge tube 110. Low power density results in low gas disassociation near the center of the linear discharge tube 110 and low deposition rates near the center of the substrate.

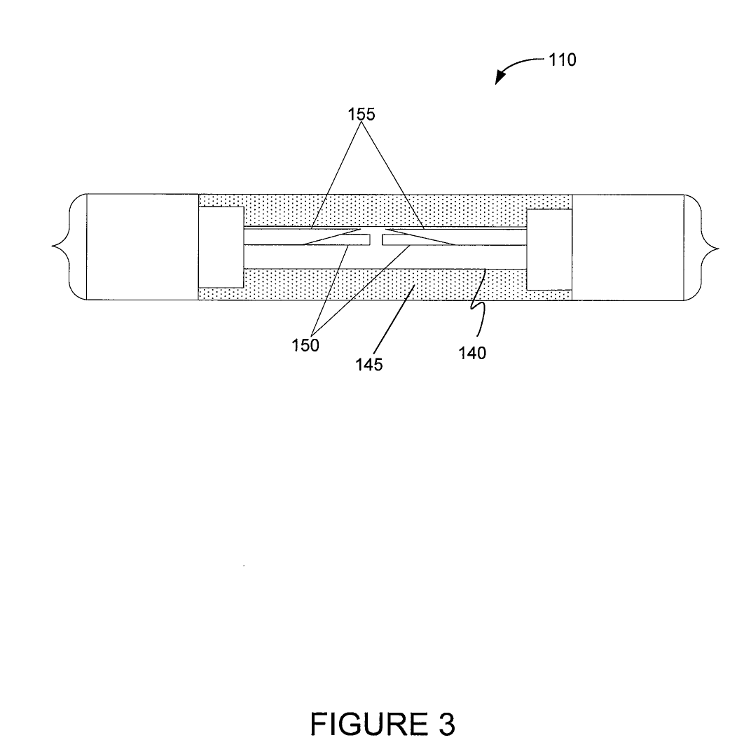

One system for addressing low plasma density near the center of the linear discharge tube 110 uses a split inner conductor. For example, two conductors are used inside the non-conductive tube. Another system, shown in FIG. 3, uses two conductors 150, such as two antennas, and metal shielding 155 placed inside the non-conductive tube 140. The metal shielding 155 and the split antenna 150 act to control the energy discharge and generate a uniform plasma density 145.

Linear discharge systems are generally driven by a power system, which can include DC supplies and/or amplifiers, coupled to a magnetron. Further enhancements to power-density uniformity and plasma uniformity along the linear discharge tube can be realized by controlling this power system. For example, plasma uniformity along the linear discharge tube can be changed by controlling the following properties of a DC signal generated by one type of power system, a DC power system: DC pulse duty cycles, pulse frequencies, and/or signal modulation. Signal modulation includes modulation of amplitude or pulse amplitude, frequency, pulse position, pulse width, duty cycle or simultaneous amplitude and any of the frequency types of modulation. Signal modulation is discussed in commonly owned and assigned attorney docket number (APPL-007/00US), entitled SYSTEM AND METHOD FOR MODULATION OF POWER AND POWER RELATED FUNCTIONS OF PECVD DISCHARGE SOURCES TO ACHIEVE NEW FILM PROPERTIES, which is incorporated herein by reference.

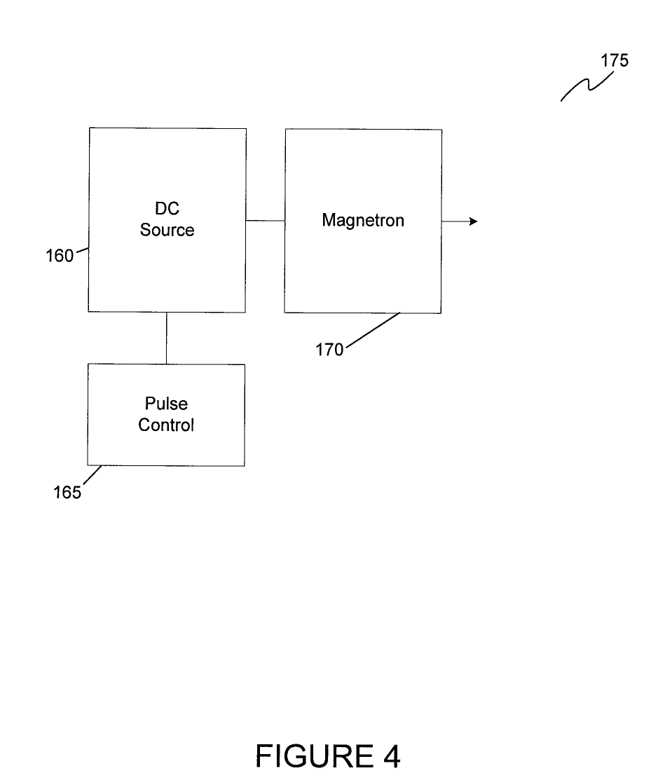

FIG. 4 illustrates a power system 175 that could be used in accordance with one embodiment of the present invention. This system includes a DC source 160 that is controllable by the pulse control 165. The terms “DC source” and “DC power supply” refer to any type of power supply, including those that use a linear amplifier, a non-linear amplifier, or no amplifier. The DC source 160 powers the magnetron 170, which generates the microwaves, or other energy waves, that drive the inner conductor within the linear discharge tube (not shown). The pulse control 165 can contour the shape of the DC pulses and adjust the set points for pulse properties such as duty cycle, frequency, and amplitude.

The pulse control 165 is also configured to modulate the DC pulses, or other energy signal, driving the magnetron 170 during the operation of the PECVD device. In some embodiments, the pulse control 165 can be configured to only modulate the signal driving the magnetron 170. In either embodiment, however, by modulating the DC pulses, the power level into the plasma can also be modulated, thereby enabling the user to control radical density and make films that were not achievable before in PECVD. This system can be used to form variable, single gradient layers or a multiple stack of hundreds to thousands of micro layers with varying properties between each other.

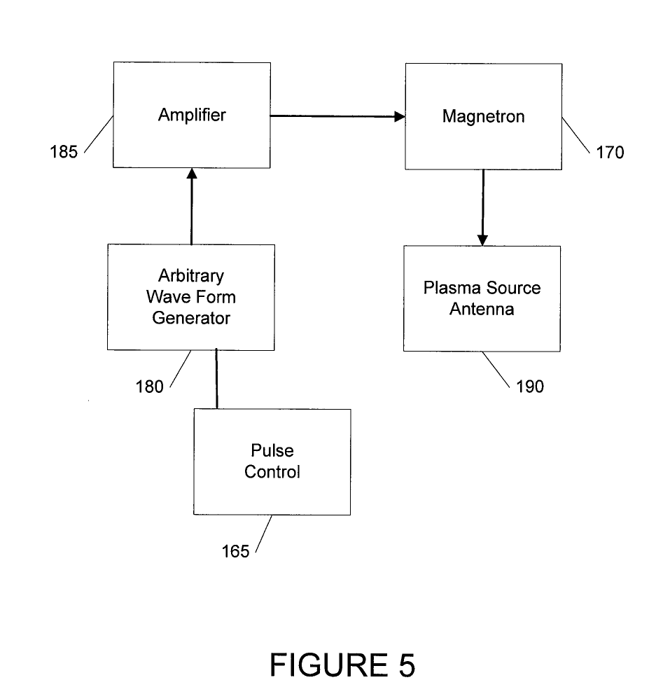

FIG. 5 illustrates an alternate embodiment of a power supply that could be used in accordance with the present invention. This embodiment includes an arbitrary waveform generator 180, an amplifier 185, a pulse control 165, a magnetron 170, and a plasma source antenna 190. In operation, the arbitrary waveform generator 180 generates a waveform and corresponding voltage that can be in virtually any form. Next, the amplifier 185 amplifies the voltage from the arbitrary waveform generator to a usable amount. In the case of a microwave generator (e.g., the magnetron 170) the signal could be amplified from +/−5VDC to 5,000VDC. Next, the high voltage signature is applied to the magnetron 170, which is a high frequency generator. The magnetron 170 generates a power output carrier (at 2.45 GHZ in this case) that has its amplitude and or frequency varied based upon the originally generated voltage signature. Finally, the output from the magnetron is applied to the plasma source antenna 190 to generate a power modulated plasma.

Signal modulation can be applied by the pulse control 165 to the arbitrary waveform generator 180. Signal modulation is a well-known process in many fields—the most well known being FM (frequency modulated) and AM (amplitude modulated) radio. But modulation has not been used before to control film properties and create layers during PECVD. Many forms of modulation exist that could be applied to a waveform power level, duty cycle or frequency, but only a few are described below. Those of skill in the art will recognize other methods. Note that modulation is different from simply increasing or decreasing the power or duty cycle of a power signal into a source.

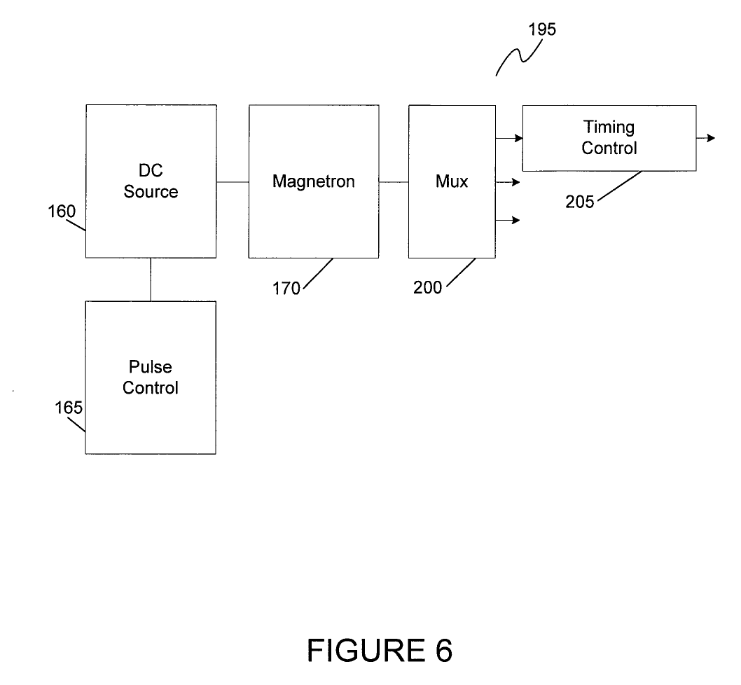

Referring now to FIG. 6, it illustrates another embodiment of a system 195 constructed in accordance with the principles of the present invention. This system includes the DC source 160 with pulse control 165 and the magnetron 170 also shown in FIG. 4. This system additionally includes a multiplexer (“Mux”) 200 and a timing control system 205. The multiplexer 200 is responsible for dividing the output of the magnetron into several signals. Each signal can then be used to power a separate linear discharge tube or separate antenna within a single linear discharge tube.

Recall that most linear discharge deposition systems include several linear discharge tubes. In certain instances, it may be desirable to offset the timing of the pulses driving adjacent linear discharge tubes. The microwaves generated by one linear discharge tube can travel to adjacent linear discharge tubes and impact power density and plasma uniformity. With proper timing control, that impact can be positive and can assist with maintaining a uniform power density and plasma. The timing control 205 can provide this timing control. These of skill in the art would understand how to tune the timing control.

The timing control 205 can also be used with linear discharge systems that include multiple magnetrons 170 and/or DC sources 160. In these systems, each linear discharge tube is driven by a separate magnetron and possibly a separate DC source. The timing control can be applied to each magnetron and/or each DC source. Again, the terms “DC source” and “DC power supply” refer to any type of power system, including those that use a linear amplifier, a non-linear amplifier, or no amplifier. The terms can also refer to an amplifier by itself.

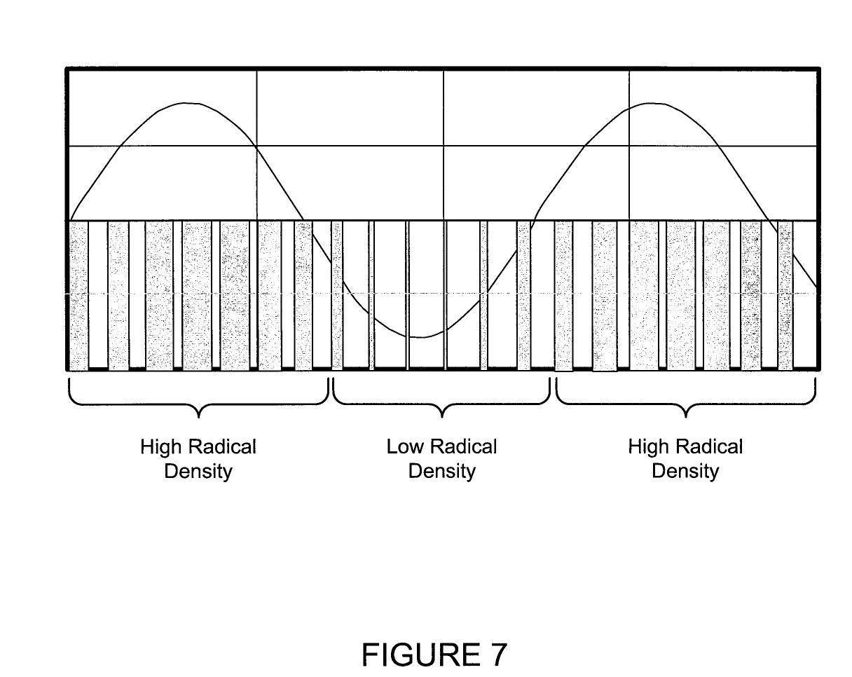

FIG. 7 illustrates pulse-width modulation, which varies the width of pulse widths over time. With pulse-width modulation, the value of a sample of data is represented by the length of a pulse.

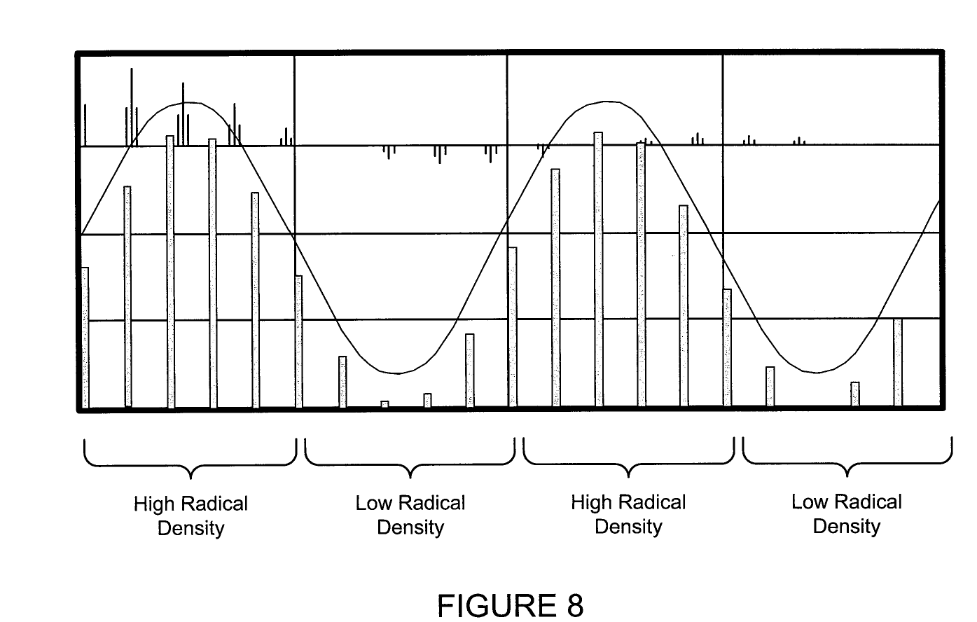

FIG. 8 illustrates pulse-amplitude modulation, which is a form of signal modulation in which the message information is encoded in the amplitude of a series of signal pulses. In the case of plasma sources the voltage, current or power level can be amplitude modulated by whatever percentage desired.

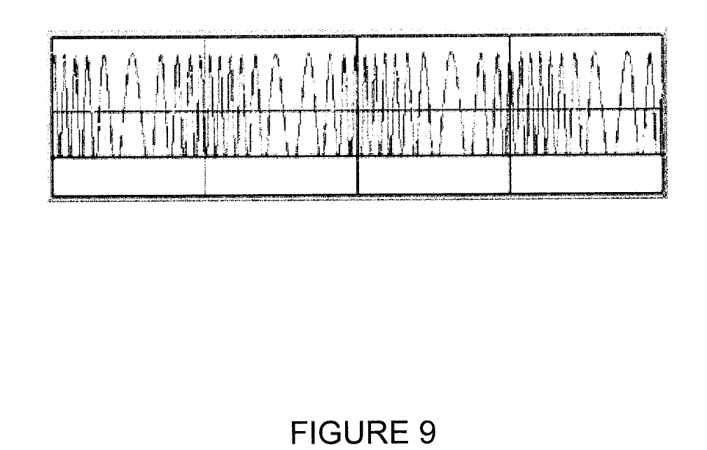

FIG. 9 illustrates frequency modulation (FM), which is the encoding of information in either analog or digital form into a carrier wave by variation of its instantaneous frequency in accordance with an input signal.

Each change to the power modulation changes directly effects the microwave power signal being introduced into the inner conductor of the linear discharge tube. Changes to the microwave power signal change the plasma uniformity around the linear discharge tube. And in many cases, changes to the DC power system can be used to control the plasma properties to thereby increase the uniformity of a chemical make up of the film. These enhancements to the power supply can be applied to single antenna systems, multiple antenna systems, multiple antenna systems with shields, etc.

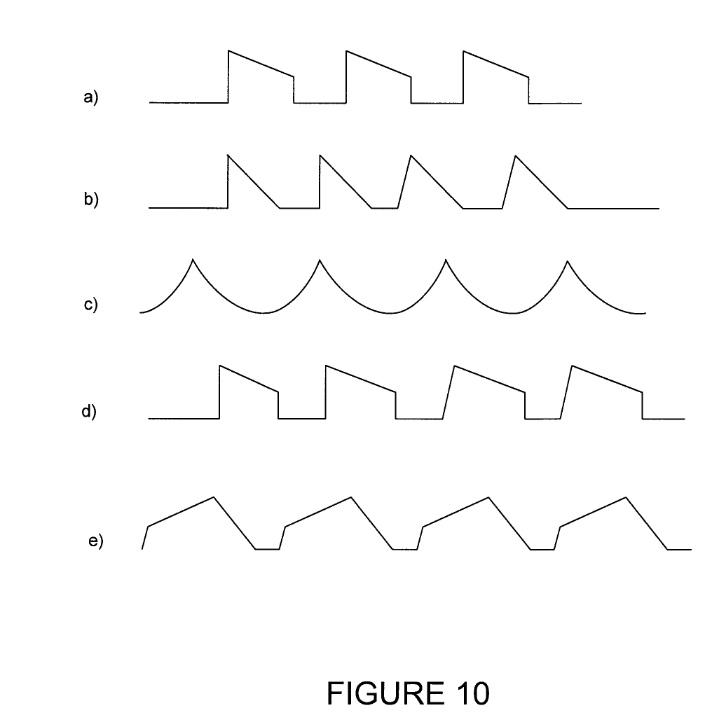

Even further enhancements to a deposition system can be realized by contouring the power density in the linear discharge tube. The power density can be contoured by contouring the power signal being introduced into the inner conductor. One method of contouring the power signal being introduced into the inner conductor involves contouring the output of the DC power system. For example, the individual pulses of the DC power system can be contoured. FIG. 10 illustrates five exemplary contoured pulses that can be used to contour the power density in a linear discharge tube. The duty cycle, frequency, amplitude, etc. of this signal can also be adjusted. The signal can also be modulated.

Particularly good results are anticipated when the degrading-pulse contours shown in FIGS. 10a, 10b, 10c and 10d are used. This degrading pulse helps maintain a uniform power density along the entire length of the linear discharge tube as the plasma ignition travels from the outer edges toward the center of the linear discharge tube. These enhancements can be applied to single antenna systems, dual antenna systems, dual antenna systems with shields, etc. These enhancements can also be used to evenly coat curved substrates as well as flat substrates because of the control of local densities.

In conclusion, the present invention provides, among other things, a system and method for controlling deposition onto substrates. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims.

What is claimed is:

1. A system for depositing films on a substrate, the system comprising:
a vacuum chamber;
a split conductor housed inside the vacuum chamber;
a magnetron configured to generate a power signal that can be applied to at least a portion of the split conductor;
a power supply configured to provide a power signal to the magnetron, the power signal including a plurality of pulses; and
a pulse control connected to the power supply, the pulse control configured to control the duty cycle of the plurality of pulses, the frequency of the plurality of pulses, and the contour shape of the plurality of pulses.

2. The system of claim 1, wherein the power signal comprises a microwave power signal.

3. The system of claim 1, wherein the split conductor comprises two partial length conductors.

4. The system of claim 3, wherein the two partial length conductors are housed within a non-conductive tube.

5. The system of claim 1, wherein the split conductor comprises a split antenna.

6. The system of claim 4, wherein the split antenna comprises a linear split antenna.

7. The system of claim 1, further comprising a timing control to control timing offset of the plurality of pulses.

8. The system of claim 1, wherein the pulse control is configured to contour the shape of one of the plurality of pulses so that the power of the one of the plurality of pulses decreases from an initial power point for the one of the plurality of pulses.

9. The system of claim 1, wherein the pulse control is configured to contour the shape of one of the plurality of pulses so that the power of the one of the plurality of pulses increases from an initial power point for the one of the plurality of pulses.

10. A method for controlling power distribution along a split conductor to deposit films on a substrate, the method comprising:
generating a DC pulse with a contoured shape;
generating a power signal using the contoured DC pulse;
providing the generated power signal to at least a portion of a split conductor;
generating a plasma at the split conductor using the generated power signal;
producing radicalized species using the generated plasma;
disassociating a gas using the radicalized species; and
depositing a portion of the disassociated gas onto a substrate.

11. The method of claim 10, wherein generating the power signal comprises generating a microwave power signal.

12. The method of claim 10, wherein the providing the generated power signal to at least the portion of the split conductor comprises providing the generated power signal to at least a portion of a split antenna.

13. The method of claim 12, wherein the providing the generated power signal to at least the portion of the split antenna comprises providing the generated power signal to at least a portion of a linear split antenna.

14. The method of claim 10, wherein the providing the generated power signal to at least the portion of the split conductor comprises providing the generated power signal to at least one of two partial length conductors.

15. The method of claim 14, wherein providing the generated power signal to at least one of two partial length conductors comprises providing the generated power signal to at least one of two partial length conductors wherein the two partial length conductors are housed within a non-conductive tube.

16. The method of claim 10, wherein generating the DC pulse with the contoured shape comprises generating the DC pulse with a contour shape that decreases from an initial power point.

17. The method of claim 10, wherein the generating the DC pulse with the contoured shape comprises generating the DC pulse with a contour shape that increases from an initial power point.

18. A method for controlling power distribution along a split conductor to deposit films on a substrate, the method comprising:
generating a first DC pulse with a contoured shape;
generating a first power signal using the contoured first DC pulse;
providing the generated first power signal to a first portion of a split conductor;
generating a second DC pulse with a contoured shape;
generating a second power signal using the contoured second DC pulse;
providing the generated second power signal to a second portion of the split conductor;
generating a plasma at the split conductor using the generated first and second power signals;
producing radicalized species using the generated plasma;
disassociating a gas using the radicalized species; and
depositing a portion of the disassociated gas onto a substrate.

19. The method of claim 18, wherein the first power signal and the second power signal are a first microwave power signal and a second microwave power signal.

20. The method of claim 18, wherein generating the second power signal using the contoured second DC pulse comprises generating the second power signal using the contoured second DC pulse, wherein the second power signal is non-synchronous with the first power signal.

21. The method of claim 20, wherein generating the second power signal using the contoured second DC pulse, wherein the second power signal is non-synchronous with the first power signal comprises generating the second power signal using the contoured second DC pulse, wherein the second power signal is non-synchronous in timing with the first power signal.

22. The method of claim 18, wherein generating the second power signal using the contoured second DC pulse comprises generating the second power signal using the contoured second DC pulse, wherein the second power signal is synchronous with the first power signal.

23. The method of claim 18, wherein the split conductor comprises a split antenna.

24. A method for controlling plasma homogeneity for film deposition, the method comprising:
generating a first plurality of contoured microwave power signal pulses;
transmitting the first plurality of contoured microwave power signal pulses through a first portion of a split conductor;
generating a second plurality of contoured microwave power signal pulses;
transmitting the second plurality of contoured microwave power signal pulses through a second portion of the split conductor;
generating a plasma at the split conductor using the generated first and second plurality of contoured microwave power signal pulses;
producing radicalized species using the generated plasma;
disassociating a gas using the radicalized species; and
depositing a portion of the disassociated gas onto a substrate.
